(19) United States
(12) Patent Application Publication
(10) Pub. No.: US 2006/0016554 A1
(43) Pub. Date: Jan. 26, 2006

(54) Substrate holder having electrostatic chuck and method of fabricating the same

(75) Inventor: Ho Kap Ahn, Anseong-city (KR)

Correspondence Address: ROTHWELL, FIGG, ERNST & MANBECK, P.C., 1425 K STREET, N.W., SUITE 800, WASHINGTON, DC, 20005, US

(73) Assignee: KoMiCo LTD., Anseong-city (KR)

(21) Appl. No.: 11/178,279

(22) Filed: Jul. 12, 2005

(30) Foreign Application Priority Data
Jul. 21, 2004 (JP) 10-2004-0056857

(51) Int. Cl. C23C 16/00; B32B 37/00; B32B 38/04

(52) U.S. Cl. 156/272.2; 118/728; 156/275.7

(57) ABSTRACT

Provided is a substrate holder including a susceptor having edge protrusion formed on edge thereof and an electrostatic chuck mounted inside the edge protrusion and on the susceptor. The electrostatic chuck is attached to the susceptor by a gel adhesive sheet containing a plurality of wires and a silicon or corrosion-resistant epoxy based material is filled between the electrostatic chuck and the edge protrusion. The planarity of the electrostatic chuck can be maintained accurately when the electrostatic chuck is attached to the susceptor and clogging of cooling gas supply holes and leakage of cooling gas through a space between the electrostatic chuck and the susceptor can be prevented.

### CROSS-REFERENCE TO RELATED PATENT APPLICATION

This application claims the benefit of Korean Patent Application No. 10-2004-0056857, filed on Jul. 21, 2004, in the Korean Intellectual Property Office, the disclosure of which is incorporated herein in its entirety by reference.

### BACKGROUND OF THE INVENTION

1. Field of the Invention

The present invention relates to a substrate holder, and more particularly, to a substrate holder having an electrostatic chuck that uses electrostatic forces to hold a semiconductor substrate. The present invention also relates to a substrate holder having an electrostatic chuck and a susceptor flatly attached to each other and a method of fabricating the same.

2. Description of the Related Art

A plasma device used in manufacturing a semiconductor device typically includes a process chamber. FIG. 1 is a cross-sectional view of a process chamber 100 including a typical substrate holder. Referring to FIG. 1, the pressure of the process chamber 100 can be controlled using a vacuum pump 180 during a plasma process. The chamber 100 includes a substrate holder 130 for holding a substrate, i.e., a wafer 110. When the wafer 110 is loaded onto the substrate holder 130 by a transport system, a high frequency power supply 170 is electrically connected to a susceptor 150 or an upper electrode (not shown) to generate plasma onto the wafer 110.

To control the temperature of the wafer 110, a cooling gas is supplied along the rear surface of the wafer 110 during an etching process and a deposition process requiring uniform etching and deposition. To accomplish this, a groove (not shown) is formed in the top surface of the electrostatic chuck 120 and a cooling gas is supplied from a cooling gas source 160 into the groove.

There are two types of electrostatic chuck 120 for holding a wafer using electrostatic forces: polyimide electrostatic chuck and anodized coating electrostatic chuck. The polyimide electrostatic chuck is formed by attaching polymer such as polyimide to the top surface of the susceptor 150. The anodized coating is formed by anodizing the surface of the susceptor 150 made of aluminum and is used as a dielectric.

While the polyimide electrostatic chuck exhibits excellent performance in terms of stacking and withstand voltage, it is vulnerable to oxygen plasma and shows a non-uniform wafer temperature distribution due to poor thermal conductivity. Anodized coating suffers variation in adhesion strength between the wafer 110 and the susceptor 150 due to a change in the dielectric constant of a dielectric layer. That is, reaction products that are formed during the process may adhere to the anodized coating that are loosely packed.

Recently, electrostatic chucks made of a ceramic material such as alumina or aluminum nitride have been introduced to address these problems.

Referring to FIG. 1, the ceramic electrostatic chuck 120 typically incorporates an electrode 140. The ceramic electrostatic chuck 120 is affixed to the top surface of the susceptor 150 by a silicon-based adhesive 190. The susceptor 150 may also be called a lower electrode for plasma generation. The ceramic electrostatic chuck 120 also has a plurality of cooling gas supply holes 161 and 162 for controlling the temperature of the wafer 110. The plurality of holes 161 and 162 penetrate the susceptor 150 and connect with the cooling gas supply 160.

The ceramic electrostatic chuck 120 may not be attached flatly to the top surface of the susceptor 150 by the silicon-based adhesive 190 due to the fluidity of the silicon-based adhesive 190. This causes several problems which will now be described with reference to FIGS. 2A-2C.

FIGS. 2A-2C are cross-sectional views of a conventional substrate holder. Referring to FIG. 2A-2C, a silicon-based gel adhesive 290 mixed with a curing agent at a predetermined ratio is applied between a ceramic electrostatic chuck 220 and a susceptor 250 and cured at predetermined pressure and temperature for attachment. The adhesive 290 has viscosity and thermal conductivity that can compensate for a difference between thermal expansion coefficients of the ceramic electrostatic chuck 220 and the susceptor 250.

Cooling gas supply holes 261 and 262 formed in the susceptor 250 must be accurately aligned with their counterparts formed in the electrostatic chuck 220 before adhesion. A slight misalignment error results in a warped cooling gas supply path and a change in the flow of cooling gas. This change causes non-uniform temperature distribution within a wafer, thereby reducing the manufacturing yields for semiconductor chips.

Predetermined temperature and pressure must be applied simultaneously when the electrostatic chuck 220 is affixed to the susceptor 250 by a silicon-based adhesive 290. Thus, when the pressure is not transferred uniformly, the adhesive 290 may concentrate on edge or center of the susceptor 250 as shown in FIGS. 2B and 2C. This degrades the planarity of the electrostatic chuck 220 or causes the creation of air bubbles through which the cooling gas leaks out when the adhesive 290 solidifies.

The conventional substrate holder has the following problems. First, when a ceramic electrostatic chuck is affixed to a susceptor, the planarity of the ceramic electrostatic chuck is difficult to precisely control depending on temperature and pressure applied because of the use of a liquid adhesive. Furthermore, the silicon adhesive tends to flow into cooling gas supply holes formed in the ceramic electrostatic chuck and the susceptor due to pressure exerted thereon, thereby resulting in clogging of the holes.

Second, pores created due to non-planarity of the electrostatic chuck and viscosity of the adhesive permits a part of cooling gas to leak from a space between the electrostatic chuck and the susceptor into a process chamber, thereby resulting in creation of an arc inside the chamber.

Thus, there is a need for a method capable of attaching the electrostatic chuck flatly to the susceptor while preventing the leakage of cooling gas due to air bubbles or for an adhesive enabling flat adhesion between the electrostatic chuck and the susceptor.

### SUMMARY OF THE INVENTION

The present invention provides a substrate holder designed to accurately maintain the planarity of a ceramic electrostatic chuck that is affixed to a susceptor while preventing clogging of cooling gas supply holes.

The present invention also provides a substrate holder designed to prevent creation of an arc due to leakage of cooling gas through pores created due to non-planarity of the electrostatic chuck and viscosity of the adhesive.

According to an aspect of the present invention, there is provided a substrate holder including a susceptor having edge protrusion formed on edge thereof and an electrostatic chuck mounted inside the edge protrusion and on the susceptor. The electrostatic chuck is attached to the susceptor by a gel adhesive sheet containing a plurality of wires and a silicon or corrosion-resistant epoxy based material is filled between the electrostatic chuck and the edge protrusion.

The shape of the plurality of wires may be meshed, concentrically circular, or radial and the contraction rate may be less than 5%. Meshed wires may be made of an optical fiber. The edge protrusion and the susceptor may be formed in one body and an upper end of the edge protrusion may be lower than or at the same level as the electrostatic chuck affixed to the susceptor.

Alternatively, the substrate holder may include: a susceptor having ring-shaped edge protrusion formed on edge thereof; and an electrostatic chuck that incorporates an electrode and is mounted inside the edge protrusion and on the susceptor.

According to another aspect of the present invention, there is provided a method of manufacturing a substrate holder including: preparing a susceptor having edge protrusion formed on edge thereof; mounting an adhesive sheet containing a plurality of wires inside the edge protrusion and on the susceptor; mounting an electrostatic chuck on the adhesive sheet; applying a pressure to the top surface of the electrostatic chuck at predetermined temperature and attaching the electrostatic chuck to the susceptor; and filling a silicon or epoxy-based material between the electrostatic chuck and the edge protrusion.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a chamber including a conventional substrate holder;

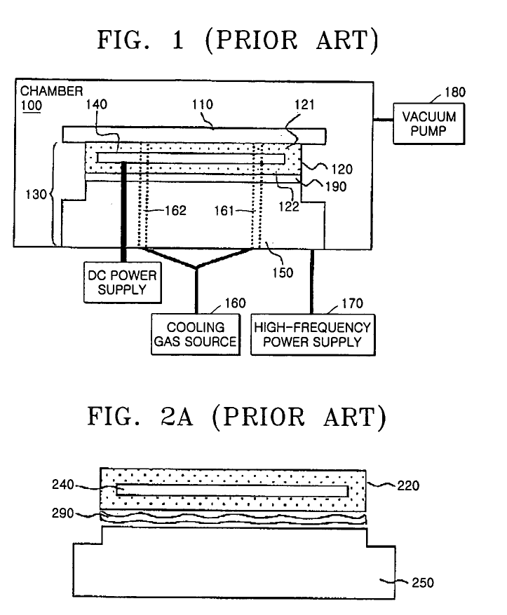

FIGS. 2A-2C are cross-sectional views of a conventional substrate holder showing an uneven distribution of an adhesive;

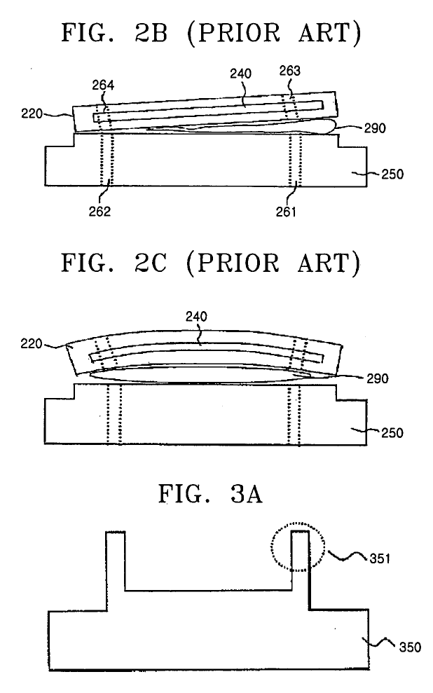

FIGS. 3A-3D are cross-sectional views schematically showing a method of manufacturing a substrate holder according to an embodiment of the present invention; and

FIG. 4 is a cross-sectional view of a substrate holder according to an embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity.

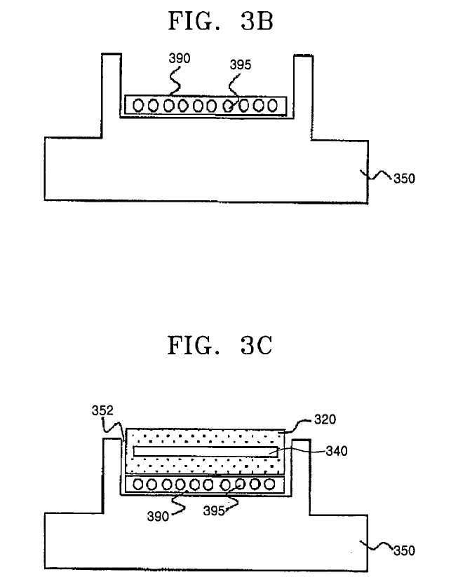

Referring to FIG. 3A, a susceptor 350 having edge protrusion 351 is prepared. The edge protrusion 351 is ring-shaped and formed integrally with the susceptor 350.

Referring to FIG. 3B, an adhesive sheet 390 containing a plurality of wires 395 is mounted inside the edge protrusion 352 of the susceptor 350 and on the susceptor 350.

Referring to FIG. 3C, a prepared ceramic electrostatic chuck 320 is affixed to the top surface of the adhesive sheet 390 by a predetermined pressure at a predetermined temperature. An electrode 340 is embedded in the electrostatic chuck 320.

The temperature and pressure is applied to attach and solidify the adhesive sheet 390. The adhesive sheet 390 may be a silicon or gel adhesive. More specifically, an available temperature range is 80 to 220° C., preferably, 100 to 180° C. An available pressure range is 2 to 20 kgf/cm².

A cooling gas path in the adhesive sheet 390 or a lift pin path may be prepatterned using hydraulic or pneumatic blanking to form holes therein. The electrostatic chuck 320 and the susceptor 350 have preformed cooling gas path and lift pin path. Because a method for forming a cooling gas path and a lift pin path is well known in the art, description thereof will not be given.

Referring to FIG. 3D, an epoxy-based material having corrosion resistance to Freon plasma or silicon is inserted into a gap 351 between the electrostatic chuck 320 and the edge protrusion 351 and cured to thereby complete a substrate holder according to an embodiment of the present invention.

The height of the ring-shaped edge protrusion 351 is less than or equal to that of the ceramic electrostatic chuck 320 that has been mounted on the susceptor 350 because a wafer cannot be attracted and held onto the electrostatic chuck 320 if the diameter of the wafer is greater than that of the electrostatic chuck 320.

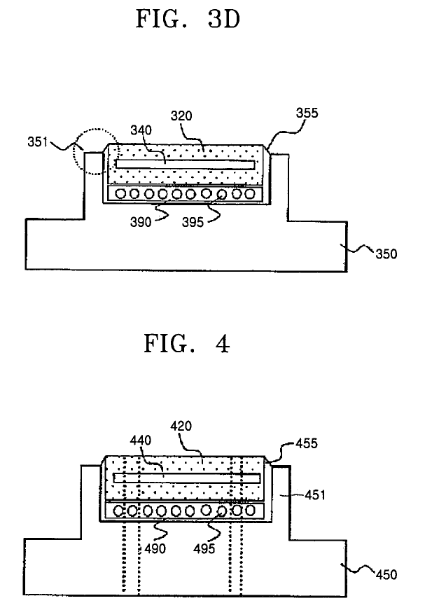

FIG. 4 is a cross-sectional view of a substrate holder according to an embodiment of the present invention. Referring to FIG. 4, an electrostatic chuck 420 of a completed substrate holder can be divided into an upper plate positioned above an electrode 440 and a lower plate positioned below the electrode 440. The upper and lower plates of the electrostatic chuck may be made of a ceramic material such as alumina, nitrided aluminum, or monocrystalline sapphire.

The electrode 440 embedded in the electrostatic chuck 420 may be formed on the lower plate of the electrostatic chuck using screen printing. The electrode 440 may be made of molybdenum (Mo) or tungsten compound containing 5 to 20% nitrided aluminum.

A plurality of wires 495 has a meshed or rounded shape and consists of a single or a plurality of layers. The wires 495 may be made of an insulating layer or optical fiber. The optical fiber may have a circular, elliptical or other-shaped cross-section. The present embodiment uses an elliptical optical fiber.

The ratio of a minor axis diameter to a major axis diameter in the elliptical optical fiber may be 1:3 to 1:7 and the contraction rate may be less than 5%.

The adhesive sheet 490 may be manufactured by inserting a gel adhesive material such as silicon or epoxy material into a gap between the meshed wires 495. The thickness of the adhesive sheet 490 that varies depending on the diameter of an optical fiber is typically 150 to 350 μm.

Furthermore, the adhesive sheet 490 may be selected over various ranges considering factors such as the thermal expansion coefficients of the electrostatic chuck 420 and the susceptor 450, viscosity, dielectric constant, volume resistivity, and thermal conductivity. The susceptor 450 is typically formed of metal such as aluminum and an anodized coating may be formed on the surface of the susceptor 450 for insulation. Edge protrusion 451 may be formed using mechanical machining.

Based on the above-mentioned configuration and manufacturing method, the electrostatic chuck is affixed to a susceptor by an adhesive sheet containing a plurality of meshed wires, thereby preventing the adhesive from flowing into a cooling gas hole or lift pin hole. Furthermore, the planarity of the electrostatic chuck can be maintained due to little variation in thickness of the adhesive sheet.

An epoxy filled between ring-shaped edge protrusion formed on the side of the susceptor and the ceramic electrostatic chuck basically prevents leakage of cooling gas from a space between the electrostatic chuck and the susceptor.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A substrate holder comprising:
a susceptor having edge protrusion formed on edge thereof; and
an electrostatic chuck mounted inside the edge protrusion and on the susceptor,
wherein the electrostatic chuck is attached to the susceptor by a gel adhesive sheet containing a plurality of wires and a silicon or corrosion-resistant epoxy based material is filled between the electrostatic chuck and the edge protrusion.

2. The substrate holder of claim 1, wherein the shape of the plurality of wires is meshed, concentrically circular, or radial, the contraction rate is less than 5%, and the meshed wires are made of an optical fiber.

3. The substrate holder of claim 1, wherein the edge protrusion and the susceptor are formed in one body and an upper end of the edge protrusion is lower than or at the same level as the electrostatic chuck affixed to the susceptor.

4. A substrate holder comprising:
a susceptor having ring-shaped edge protrusion formed on edge thereof; and
an electrostatic chuck that incorporates an electrode and is mounted inside the edge protrusion and on the susceptor.

5. A method of manufacturing a substrate holder comprising:
preparing a susceptor having edge protrusion formed on edge thereof;
mounting an adhesive sheet containing a plurality of wires inside the edge protrusion and on the susceptor;
mounting an electrostatic chuck on the adhesive sheet;
applying a pressure to the top surface of the electrostatic chuck at predetermined temperature and attaching the electrostatic chuck to the susceptor; and
filling a silicon or epoxy-based material between the electrostatic chuck and the edge protrusion.
